(19) United States
(12) Patent Application Publication
(10) Pub. No.: US 2005/0129869 A1
(43) Pub. Date: Jun. 16, 2005

(54) Article protected by a thermal barrier coating having a group 2 or 3/group 5 stabilization-composition-enriched surface

(75) Inventors: John Frederick Ackerman, Laramie, WY (US); Venkat Subramanian Venkataramani, Clifton Park, NY (US); Irene T. Spitsberg, Loveland, OH (US); Brett Allen Rohrer Boutwell, Liberty Township, OH (US); Ramgopal Darolia, West Chester, OH (US)

Correspondence Address: MCNEES WALLACE & NURICK LLC, 100 PINE STREET, P.O. BOX 1166, HARRISBURG, PA, 17108-1166, US

(73) Assignee: General Electric Company, Schenectady, NY (US)

(21) Appl. No.: 10/735,369

(22) Filed: Dec. 12, 2003

(51) Int. Cl. C23C 16/00; B05D 1/08

(52) U.S. Cl. 427/454; 427/252; 427/395; 427/248.1

(57) ABSTRACT

A protected article is prepared by providing the article, depositing a bond coat onto an exposed surface of the article, and producing a thermal barrier coating on an exposed surface of the bond coat. The step of producing the thermal barrier coating includes the steps of depositing a primary ceramic coating onto an exposed surface of the bond coat, and depositing a stabilization composition onto an exposed surface of the primary ceramic coating. The stabilization composition includes a first element selected from Group 2 or Group 3 of the periodic table, and a second element selected from Group 5 of the periodic table. The atomic ratio of the amount of the first element to the amount of the second element is at least 1:3, more preferably at least 1:1.

This invention relates to the thermal barrier coating used to protect an article such as a nickel-base superalloy substrate and, more particularly, to the inhibiting of the sintering between the grains of the thermal barrier coating.

### BACKGROUND OF THE INVENTION

A thermal barrier coating system may be used to protect the components of a gas turbine engine that are subjected to the highest temperatures. The thermal barrier coating system usually includes a bond coat that is deposited upon a superalloy substrate, and a ceramic thermal barrier coating that is deposited upon the bond coat. The thermal barrier coating acts as a thermal insulator against the heat of the hot combustion gas. The bond coat bonds the thermal barrier coating to the substrate and also inhibits oxidation and corrosion of the substrate.

The currently preferred thermal barrier coating is yttria-stabilized zirconia (YSZ), which is zirconia (zirconium oxide) with from about 2 to about 12 percent by weight yttria (yttrium oxide). The yttria is present to stabilize the zirconia against phase changes that otherwise occur as the thermal barrier coating is heated and cooled during fabrication and service. The YSZ is deposited by a physical vapor deposition process such as electron beam physical vapor deposition. In this deposition process, the grains of the YSZ form as columns extending generally outwardly from and perpendicular to the surfaces of the substrate and the bond coat.

When the YSZ is initially deposited, there are small gaps between the generally columnar grains. On examination at high magnification, the generally columnar grains are seen to have a somewhat feather-like morphology characterized by these gaps oriented over a range of angles relative to the substrate surface. The gaps serve to accommodate the transverse thermal expansion strains of the columnar grains and also act as an air insulator in the structure. As the YSZ is exposed to elevated temperatures during service, these gaps close by a surface-diffusion sintering mechanism. The result is that the ability of the YSZ to accommodate thermal expansion strains is reduced, and the thermal conductivity of the YSZ increases by about 20 percent or more. The as-deposited thickness of the YSZ must therefore be greater than would otherwise be desired, to account for the loss of insulating capability associated with this rise in thermal conductivity during service.

It has been recognized that the addition of sintering inhibitors to the YSZ reduces the tendency of the gaps between the columnar grains to close by sintering during service of the thermal barrier coating. A number of sintering inhibitors have been proposed. However, these sintering inhibitors have various shortcomings, and there is a need for more effective sintering inhibitors. The present invention fulfills this need, and further provides related advantages.

### BRIEF SUMMARY OF THE INVENTION

The present invention provides an article protected by a thermal barrier coating system, and a method for its fabrication. The thermal barrier coating includes an effective surface-stabilization composition that inhibits sintering and thereby slows or prevents the closure of the gaps between the columnar grains. The sintering inhibitors are readily introduced into the thermal barrier coating by an infiltration technique.

A method for preparing a protected article comprises the steps of providing the article, depositing a bond coat onto an exposed surface of the article, and producing a thermal barrier coating on an exposed surface of the bond coat. The step of producing the thermal barrier coating includes the steps of depositing a primary ceramic coating onto an exposed surface of the bond coat, and depositing a stabilization composition onto an exposed surface of the primary ceramic coating, so that the stabilization composition is infiltrated into the exposed surface of the primary ceramic coating. The stabilization composition comprises a first element selected from Group 2 or Group 3 of the periodic table, and a second element selected from Group 5 of the periodic table. (All references to “Group” here are to the appropriate group of the periodic table.) The “first element” may be various Group 2 elements or various Group 3 elements, or a mixture of elements selected from both Group 2 and Group 3. The second element may be mixtures of various Group 5 elements. The structure with the stabilization composition at its surface is preferably, but not necessarily, heated to diffuse the stabilization composition and form oxides from the infiltrated cations.

The article is preferably a component of a gas turbine engine, such as a turbine blade or vane. The article is preferably made of a nickel-base superalloy.

The bond coat is preferably a diffusion aluminide or an aluminum-containing overlay bond coat.

The primary ceramic coating is preferably yttria-stabilized zirconia (YSZ), typically with about 2-12 weight percent yttria. Preferably, the primary ceramic coating is YSZ with about 7 weight percent yttria, balance zirconia.

The first element is preferably selected from Group 3, more preferably from Group 3b, and most preferably yttrium or a lanthanide. The second element is preferably selected from Group 5b, more preferably niobium or tantalum, and vanadium is not preferred.

More specifically, the first element is preferably lanthanum, neodymium, yttrium, or cerium. The second element is preferably tantalum or niobium. The stabilization composition most preferably comprises two elements selected from the group consisting of lanthanum and tantalum, neodymium and tantalum, lanthanum and niobium, neodymium and niobium, cerium and tantalum, yttrium and tantalum, and yttrium and niobium.

A particularly preferred stabilization composition includes cerium and tantalum. The cerium is in the +3 valence state, which is a large, slowly diffusing species with a high tendency to segregate to the grain boundaries. Formation of tantalates may also occur.

The deposition of the stabilization composition is preferably accomplished by co-depositing the first element and the second element, most preferably from a liquid solution.

The Group 5 element, preferably tantalum or niobium, enters the lattice on its surface and reduces the oxygen vacancies. The pairing of Group 2 or Group 3 elements with Group 5 elements in the stabilization composition produces an electron compensation effect in relation to the Group 4 zirconium, which is the preferred cation for the oxide of the primary ceramic coating. By contrast, a single added cationic species cannot achieve this charge-compensation effect. The result of the present approach is a reduced defect structure at the surface of the primary ceramic coating. The reduced defect structure results in a reduced rate of surface diffusion in the primary ceramic coating, with a corresponding reduced rate of sintering and closure of the desirable gaps within the primary ceramic coating.

In the present approach wherein Group 2/3 elements are used in conjunction with the Group 5 elements, the differences in the ionic radius of the associated cations produces stress fields in the zirconia lattice. The Group 2/3 cations have a radius that is larger than zirconia and yttria, and produce a compressive stress field. The Group 5 cations are smaller than the yttria, producing a tensile stress field. The two different cations when used together are attracted to each other to minimize the lattice stress and distortion. The result is reduced diffusion since both oxide cations would have to diffuse together to keep the stress field minimized.

Additionally, the Group 3/5 and Group 5 cations have the potential to form complex compounds such as tantalates. The formation of these complex oxide compounds also slows diffusion because it is more difficult to move the complex oxide structure through the lattice. The sintering response of the ceramic is thereby reduced, especially at the surface of the ceramic columns where the Group 2/3 and Group 5 oxides would initially have the highest concentration.

The atomic ratio of the amount of the first (Group 2 or Group 3) element to the amount of the second (Group 5) element is at least 1:3, more preferably at least 1:1 (i.e., 3:3). In the preferred case of the atomic ratio of 1:1, there are as many atoms of, or more atoms than, the first element than the second element. If there is an atomic excess of the Group 5 second element, sintering is promoted, the opposite of the desirable retardation that is achieved in the present approach.

Other features and advantages of the present invention will be apparent from the following more detailed description of the preferred embodiment, taken in conjunction with the accompanying drawings, which illustrate, by way of example, the principles of the invention. The scope of the invention is not, however, limited to this preferred embodiment.

### BRIEF DESCRIPTION OF THE DRAWINGS

FIG. 1 is a block flow diagram of an approach for practicing the invention;

FIG. 2 is a perspective view of a turbine blade;

FIG. 3 is an enlarged sectional view of the surface region of the airfoil portion of the turbine blade, taken along line 3-3; and

FIG. 4 is an enlarged detail of FIG. 3, taken in region 4.

### DETAILED DESCRIPTION OF THE INVENTION

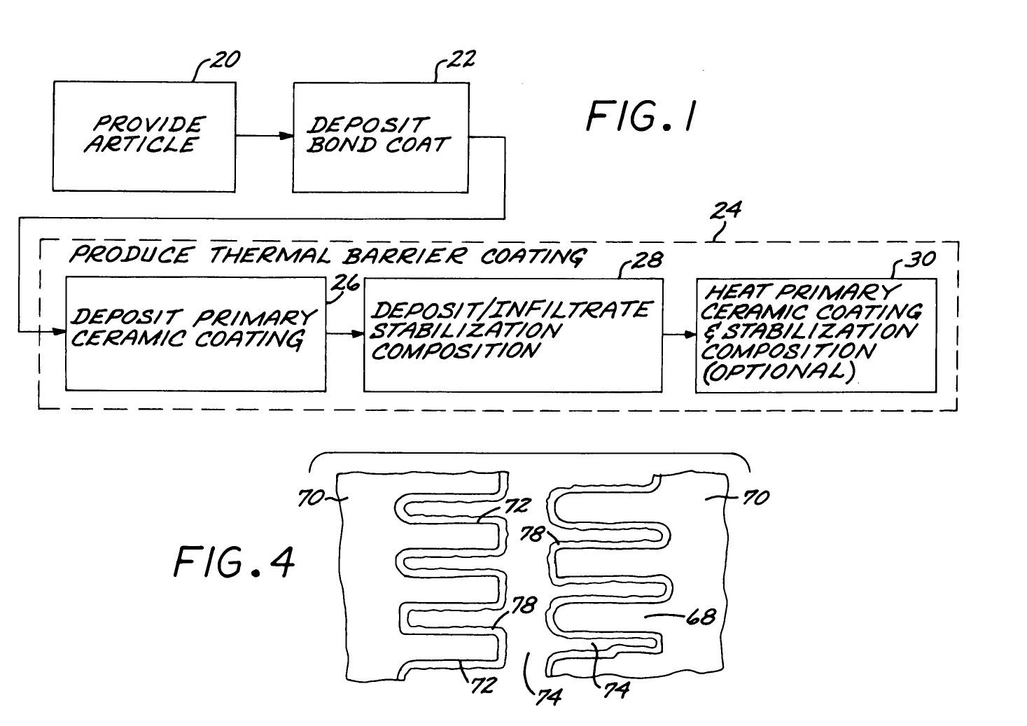

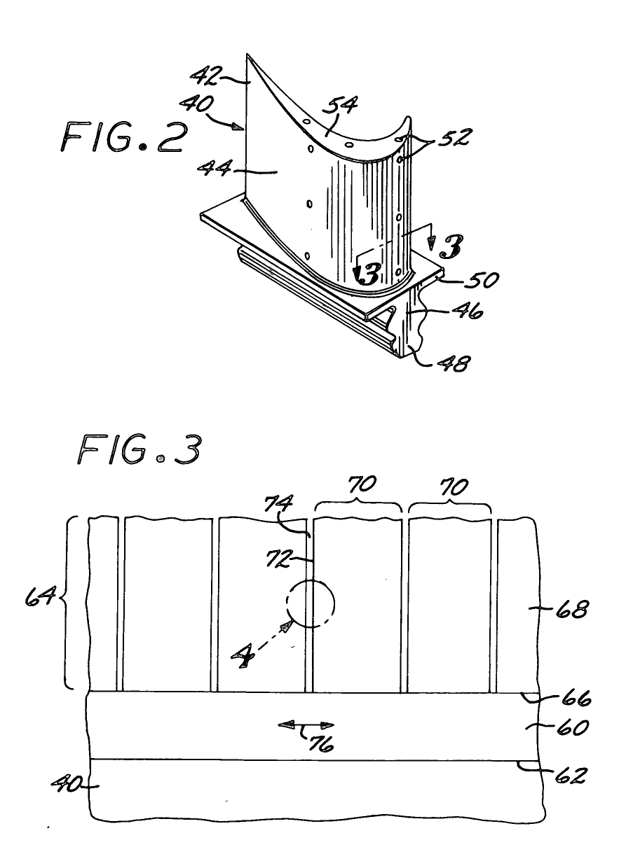

FIG. 1 depicts a preferred embodiment of one approach for practicing the invention. An article is provided, step 20. The article is preferably a component of a gas turbine engine, such as a turbine blade or a turbine vane. An example of such an article 40 is a gas turbine blade 42 illustrated in FIG. 2. The gas turbine blade 42 has an airfoil 44 against which a flow of hot combustion gas impinges during service operation, a downwardly extending shank 46, and an attachment 48 in the form of a dovetail, which attaches the gas turbine blade 42 to a gas turbine disk (not shown) of the gas turbine engine. A platform 50 extends transversely outward at a location between the airfoil 44, on the one hand, and the shank 46 and the attachment 48, on the other hand. There may be internal cooling passages through the interior of the gas turbine blade 42, ending in openings 52 on the airfoil 44 and/or at the tip 54 of the gas turbine blade 42. The gas turbine blade 42 may have a random polycrystalline grain structure, but more preferably it has a single-crystal or directionally oriented polycrystal grain structure.

The gas turbine blade 42 is preferably made of a nickel-base superalloy. As used herein, “nickel-base” means that the composition has more nickel present by weight than any other element. The nickel-base superalloys are typically of a composition that is strengthened by the precipitation of gamma-prime phase or a related phase. A typical nickel-base superalloy falls within a composition range, in weight percent, of from about 4 to about 20 percent cobalt, from about 1 to about 10 percent chromium, from about 5 to about 7 percent aluminum, from 0 to about 2 percent molybdenum, from about 3 to about 8 percent tungsten, from about 4 to about 12 percent tantalum, from 0 to about 2 percent titanium, from 0 to about 8 percent rhenium, from 0 to about 6 percent ruthenium, from 0 to about 1 percent niobium, from 0 to about 0.1 percent carbon, from 0 to about 0.01 percent boron, from 0 to about 0.1 percent yttrium, from 0 to about 1.5 percent hafnium, balance nickel and incidental impurities, although nickel-base superalloys may have compositions outside this range. A nickel-base superalloy of particular interest is Rene® N5, a registered trademark assigned to Teledyne Industries, Inc., of Los Angeles, Calif., having a nominal composition in weight percent of about 7.5 percent cobalt, about 7.0 percent chromium, about 1.5 percent molybdenum, about 5 percent tungsten, about 3 percent rhenium, about 6.5 percent tantalum, about 6.2 percent aluminum, about 0.15 percent hafnium, about 0.05 percent carbon, about 0.004 percent boron, about 0.01 percent yttrium, balance nickel and minor elements.

A bond coat 60 is deposited onto an exposed surface 62 of the article 40, step 22. (As used herein, an “exposed surface” is a surface which is initially exposed and not contacting anything else, and upon which a layer or coating is deposited. After the deposition, the previously exposed surface is no longer exposed, but is covered with the layer or coating.) The bond coat 60 may be of any operable type. The bond coat 60 may be a diffusion aluminide bond coat, produced by depositing an aluminum-containing layer onto the free surface 62 and interdiffusing the aluminum-containing layer with the article 40 to produce an additive layer and a diffusion zone. The bond coat may be a simple diffusion aluminide, or it may be a more-complex diffusion aluminide wherein another layer, preferably platinum, is first deposited upon the surface 62, and the aluminum-containing layer is deposited over the first-deposited layer. In either case, the aluminum-containing layer may be doped with other elements that modify the bond coat. The bond coat may instead be an overlay coating such as an MCrAlX coating. The terminology “MCrAlX” is a shorthand term of art for a variety of families of overlay bond coats 60 that may be employed as environmental coatings or bond coats in thermal barrier coating systems. In this and other forms, M refers to nickel, cobalt, iron, and combinations thereof. In some of these protective coatings, the chromium may be omitted. The X denotes elements such as hafnium, zirconium, yttrium, tantalum, rhenium, ruthenium, palladium, platinum, silicon, titanium, boron, carbon, and combinations thereof. Specific compositions are known in the art. Some examples of MCrAlX compositions include, for example, NiAlCrZr and NiAlZr, but this listing of examples is not to be taken as limiting. In each case, the bond coat 60 is typically from about 0.0005 to about 0.010 inch thick. Such bond coats 60 and their deposition procedures are generally known in the art.

Because the platinum-aluminide diffusion aluminide is preferred, its deposition will be described in more detail. A platinum-containing layer is first deposited onto the exposed surface 62 of the article 40. The platinum-containing layer is preferably deposited by electrodeposition. For the preferred platinum deposition, the deposition is accomplished by placing a platinum-containing solution into a deposition tank and depositing platinum from the solution onto the exposed surface 62 of the article 40. An operable platinum-containing aqueous solution is Pt(NH₃)₄HPO₄ having a concentration of about 4-20 grams per liter of platinum, and the voltage/current source is operated at about ½-10 amperes per square foot of facing article surface. The platinum first coating layer, which is preferably from about 1 to about 6 micrometers thick and most preferably about 5 micrometers thick, is deposited in 1-4 hours at a temperature of 190-200° F.

A layer comprising aluminum- and any modifying elements is deposited over the platinum-containing layer by any operable approach, with chemical vapor deposition preferred. In that approach, a hydrogen halide activator gas, such as hydrogen chloride, is contacted with aluminum metal or an aluminum alloy to form the corresponding aluminum halide gas. Halides of any modifying elements are formed by the same technique. The aluminum halide (or mixture of aluminum halide and halide of the modifying element, if any) contacts the platinum-containing layer that overlies the surface 62 of the article 40, which serves as the deposition substrate, depositing the aluminum thereon. The deposition occurs at elevated temperature such as from about 1825° F. to about 1975° F. so that the deposited aluminum atoms interdiffuse with the platinum layer and the article 40 during a 4 to 20 hour cycle.

A thin aluminum oxide (alumina, Al₂O₃) scale forms on the surface of the bond coat 60 by oxidation of the aluminum that is in the bond coat 60 at its exposed surface 66. The aluminum oxide is a protective oxide that inhibits further oxidation of the bond coat. The aluminum oxide scale may be formed by reaction with residual oxygen during fabrication, or during service of the article, or both.

A thermal barrier coating 64 is produced on the exposed surface 66 (and overlying the thin aluminum oxide scale) of the bond coat 60, step 24. The production of the thermal barrier coating 64 includes first depositing a primary ceramic coating 68 onto the exposed surface 66 of the bond coat 60, step 26. The primary ceramic coating 68 is deposited, step 26, preferably by a physical vapor deposition process such as electron beam physical vapor deposition (EBPVD) or by air plasma spray (APS). The primary ceramic coating 68 is preferably from about 0.003 to about 0.010 inch thick, most preferably about 0.005 inch thick. The primary ceramic coating 68 is preferably yttria-stabilized zirconia (YSZ), which is zirconium oxide containing from about 2 to about 12 weight percent, more preferably from about 4 to about 8 weight percent, most preferably about 7 percent, of yttrium oxide. Other operable ceramic materials may be used as well. Examples include yttria-stabilized zirconia, which has been modified with additions of “third” oxides such as lanthanum oxide, ytterbium oxide, gadolinium oxide, neodymium oxide, tantalum oxide, or mixtures of these oxides, which are co-deposited with the YSZ.

As illustrated schematically in FIGS. 3 and 4 (an enlargement of a portion of FIG. 3), when prepared by a physical vapor deposition process the primary ceramic coating 68 is formed primarily of a plurality of columnar grains 70 of the ceramic material that are affixed at their roots to the bond coat 60 (and to the alumina scale that forms on the bond coat 60). The columnar grains 70 of the primary ceramic coating 68 have exposed surfaces 72. As seen in FIG. 4, the sides of the columnar grains 70 tend to be somewhat featherlike in morphology. There are gaps 74, whose size is exaggerated in FIGS. 3 and 4 for the purposes of illustration, between the facing exposed surfaces 72 of the columnar grains 70.

This morphology of the primary ceramic coating 68 is beneficial to the functioning of the thermal barrier coating 64. The gaps 74 are filled with air, which when relatively stagnant between the grains 70 is an effective thermal insulator, aiding the thermal barrier coating 64 in performing its primary role. Additionally, the gaps 74 allow the article 40, the bond coat 60 with its alumina scale, and the thermal barrier coating 64 to expand and contract in a transverse direction 76 that is locally parallel to the plane of the surface 62. Absent the gaps 74, the in-plane thermal stresses (i.e., parallel to the transverse direction 76) that are induced in the thermal barrier coating 64 as the article 40 is heated and cooled are developed across the entire extent of the thermal barrier coating 64. The thermal barrier coating 64, being a ceramic, has a generally low ductility so that the accumulated stresses would be more likely to cause premature failure. With the gaps 74 present, as illustrated, the in-plane stresses in the thermal barrier coating 64 are developed across only one or at most a group of a few of the columnar grains 70. That is, all of the grains 70 have in-plane stresses, but the magnitude of the in-plane stresses is relatively low because the strains do not accumulate over long distances. The result is that the thermal barrier coating 64 with the columnar grains 70 and gaps 74 is less likely to fail by in-plane overstressing during service.

During the exposure to elevated temperature of the article 40 during service, the facing exposed surface 72 tend to grow toward each other, bond together, and sinter together. The sizes of the gaps 74 are gradually reduced and eventually eliminated. The beneficial effects discussed above are thereby gradually reduced and eventually lost.

The present approach provides for depositing a stabilization composition 78 onto the exposed surface 72 of the primary ceramic coating 68 and infiltrating the stabilization composition 78 into the exposed surface 72 and thence into the near-surface regions of the primary ceramic coating 68, step 28. The stabilization composition 78 includes a first element selected from Group 2 and/or Group 3 of the periodic table, and a second element selected from Group 5 of the periodic table. The first element is preferably lanthanum, neodymium, or cerium. The second element is preferably tantalum or niobium. The stabilization composition most preferably comprises two elements selected from the group consisting of lanthanum and tantalum, neodymium and tantalum, lanthanum and niobium, neodymium and niobium, and cerium and tantalum. A particularly preferred stabilization composition includes cerium and tantalum.

The atomic ratio of the amount of the first element to the amount of the second element is at least 1:3 (for example, LaTa₃O₉), more preferably at least 1:1 (for example, La₃TaO₇, where the ratio is 3:1). In the preferred case of an atomic ratio of 1:1, there must be as many atoms of, or more atoms than, the first element than the second element. If there is an atomic excess of the Group 5 second element, sintering is promoted, the opposite of the desirable sintering retardation that is achieved in the present approach, although that effect may be tolerated to some degree.

The first element and the second element of the stabilization composition 78 are preferably co-deposited from a solution. Examples of solutions for such co-deposition include aqueous citrates, chlorides, and acetates.

The stabilization composition 78 optionally may be heated, step 30, in an oxygen-containing atmosphere to further infiltrate the stabilization composition 78 into the primary ceramic coating 68 and to stabilize the thermal barrier coating 64. The heating 30 also may chemically react the stabilization composition 78 to form oxides adjacent to the exposed surface 72 of the primary ceramic coating 68. An example of such a heating 30 is to a temperature of from about 600° C. to about 1200° C., and for a time of from about 1 to about 12 hours. The oxidation step 30 is optional, because the thermal barrier coating 64 is normally subsequently heated in service in any event.

Although a particular embodiment of the invention has been described in detail for purposes of illustration, various modifications and enhancements may be made without departing from the spirit and scope of the invention. Accordingly, the invention is not to be limited except as by the appended claims.

1. A method for preparing a protected article, comprising the steps of
providing the article;
depositing a bond coat onto an exposed surface of the article; and
producing a thermal barrier coating on an exposed surface of the bond coat, wherein the step of producing the thermal barrier coating includes the steps of
depositing a primary ceramic coating onto an exposed surface of the bond coat, and
depositing a stabilization composition onto an exposed surface of the primary ceramic coating, wherein the stabilization composition comprises a first element selected from Group 2 or Group 3 of the periodic table, and a second element selected from Group 5 of the periodic table, and wherein the atomic ratio of the amount of the first element to the amount of the second element is at least 1:3.

2. The method of claim 1, wherein the step of providing the article includes the step of
providing the article as a nickel-base superalloy article.

3. The method of claim 1, wherein step of providing the article includes the step of
providing the article in the form of a component of a gas turbine engine.

4. The method of claim 1, wherein the step of depositing the bond coat includes the step of
depositing a diffusion aluminide or an aluminum-containing overlay bond coat.

5. The method of claim 1, wherein the step of depositing the primary ceramic coating includes the step of
depositing yttria-stabilized zirconia as the primary ceramic coating.

6. The method of claim 1, wherein the step of depositing the stabilization composition includes the step of
providing the first element selected from the group consisting of lanthanum, neodymium, and cerium.

7. The method of claim 1, wherein the step of depositing the stabilization composition includes the step of
providing the second element selected from the group consisting of tantalum and niobium.

8. The method of claim 1, wherein the step of depositing the stabilization composition comprises the step of
depositing the stabilization composition selected from the group consisting of lanthanum and tantalum, neodymium and tantalum, lanthanum and niobium, neodymium and niobium, and cerium and tantalum.

9. The method of claim 1, wherein the step of depositing the stabilization composition includes the step of
co-depositing the first element and the second element.

10. The method of claim 1, wherein the step of depositing the stabilization composition includes the step of
co-depositing the first element and the second element from a liquid solution.

11. The method of claim 1, wherein the step of depositing the stabilization composition includes the step of
depositing the stabilization compound such that the atomic ratio of the amount of the first element to the amount of the second element is at least 1:1.

12. A method for preparing a protected article, comprising the steps of
providing a nickel-base superalloy article that is a component of a gas turbine engine;
depositing a bond coat onto an exposed surface of the article; and
producing a thermal barrier coating on an exposed surface of the bond coat, wherein the step of producing the thermal barrier coating includes the steps of
depositing a yttria-stabilized zirconia primary ceramic coating onto an exposed surface of the bond coat,
infiltrating a stabilization composition into an exposed surface of the primary ceramic coating, wherein the stabilization composition comprises a first element selected from Group 2 or Group 3 of the periodic table, and a second element selected from Group 5 of the periodic table, and wherein the atomic ratio of the amount of the first element to the amount of the second element is at least 1:3.

13. The method of claim 12, wherein the step of depositing the primary ceramic coating includes the step of
depositing yttria-stabilized zirconia having about 7 percent yttria by weight.

14. The method of claim 12, wherein the step of depositing the bond coat includes the step of
depositing a diffusion aluminide or an aluminum-containing overlay bond coat.

15. The method of claim 12, wherein the step of infiltrating the stabilization composition includes the step of
providing the first element selected from the group consisting of lanthanum, neodymium, and cerium.

16. The method of claim 12, wherein the step of infiltrating the stabilization composition includes the step of
providing the second element selected from the group consisting of tantalum and niobium.

17. The method of claim 12, wherein the step of infiltrating the stabilization composition comprises the step of
deposition the stabilization composition selected from the group consisting of lanthanum and tantalum, neodymium and tantalum, lanthanum and niobium, neodymium and niobium, and cerium and tantalum.

18. The method of claim 12, wherein the step of infiltrating the stabilization composition includes the step of
co-depositing the first element and the second element.

19. The method of claim 12, wherein the step of depositing the stabilization composition includes the step of
depositing the stabilization compound such that the atomic ratio of the amount of the first element to the amount of the second element is at least 1:1.

20. A method for preparing a protected article, comprising the steps of
providing the article;
depositing a bond coat onto an exposed surface of the article; and
producing a thermal barrier coating on an exposed surface of the bond coat, wherein the thermal barrier coating comprises
a primary ceramic coating on the exposed surface of the bond coat, and
a sintering-inhibitor region at a surface of the primary ceramic coating, wherein the sintering-inhibitor region comprises a first element selected from Group 2 or Group 3 of the periodic table, and a second element selected from Group 5 of the periodic table, and wherein the atomic ratio of the amount of the first element to the amount of the second element is at least 1:3.
